(19) United States
(12) Patent Application Publication
(10) Pub. No.: US 2013/0228210 A1
(43) Pub. Date: Sep. 5, 2013

(54) Low Cost High Efficiency Solar Concentrator With Tracking Receivers

(71) Applicants: Roland Winston, Merced, CA (US); Weiya Zhang, Merced, CA (US)

(72) Inventors: Roland Winston, Merced, CA (US); Weiya Zhang, Merced, CA (US)

(73) Assignee: The Regents of the University of California, Oakland, CA (US)

(21) Appl. No.: 13/819,665

(22) PCT Filed: Aug. 29, 2011
(86) PCT No.: PCT/US11/49582

§ 371 Date: May 9, 2013

Related U.S. Application Data
(60) Provisional application No. 61/378,304, filed on Aug. 30, 2010.

(51) Int. Cl. H01L 31/052; H01L 35/28; F24J 2/38

(52) U.S. Cl. CPC H01L 31/0525; F24J 2/38; H01L 35/28
USPC 136/246; 126/600; 136/206; 126/634; 126/573; 126/714; 29/890.033

(57) ABSTRACT

One embodiment of the invention relates to a light concentrator apparatus including a reflector with an open substantially hemispherical reflecting surface characterized by a radius R, and an aperture for admitting light onto the hemispherical reflecting surface. The light concentrator apparatus further includes a movable elongated light collector having a first end located proximal to the reflecting surface; and extending along a longitudinal axis in a direction substantially normal to the reflecting surface to a second end. The light concentrator further includes a tracker configured to move the first end of the collector to points proximal to the reflecting surface.

### CROSS-REFERENCE TO RELATED PATENT APPLICATIONS

This application claims priority under 35 U.S.C. §119(e) to U.S. Provisional Application No. 61/378,304, filed Aug. 30, 2010, the contents of which is incorporated by reference in its entirety into the present application.

### BACKGROUND

This disclosure relates to the concentration of light, and, more particularly, the concentration of light using an optical element.

The utilization of renewable energy sources is becoming popular as a way to reduce the dependence on fossil fuels and to decrease the emissions of pollutants and green-house gases into the atmosphere. Solar thermal systems provide the capability of generating heat, electric power, and/or cooling in a sustainable way and for a variety of applications due to the relatively large range of temperatures that different collector configurations can provide. Readily available in the market, solar collectors vary in performance depending on their design. The effective transfer of the heat obtained from the sun to the heat-transfer fluid remains a subject of continued research.

Typically, light concentrators are designed to receive light incident over a range of angles less than an acceptance angle at an aperture. The light is concentrated onto a region (e.g., on an absorber) with an area smaller than the area of the aperture. The ratio of the aperture area to the smaller area is known as the geometric concentration. The laws of thermodynamics set a theoretical upper bound, known in the art as the “thermodynamic limit,” to the concentration for a given concentrator configuration. Many types of solar concentrators have been studied including reflective and refractive devices. Concentrators may be imaging or non imaging, and may be designed to correct for various types of optical aberration (spherical aberration, coma, astigmatism, chromatic aberration, etc.).

To effectively capture more of the available sunlight, concentrators and or the solar cells may be configured to move over the course of the day to follow or track the position of the sun as it changes over the course of the day and over the course of the year. Such tracking systems may move along a single axis or multiple axis and may be either passive systems or active systems that use electrical motors or other powered devices to move the solar energy system. Tracking systems add an additional source of complexity and cost to a solar energy system.

### SUMMARY

The inventor has realized that a low cost, high efficiency solar concentrator as described herein may be provided. In some embodiments, the concentrator includes a hemisphere shaped reflector which efficiently concentrates light onto an elongated collector. Embodiments of the hemisphere shaped reflector in combination with the other devices and techniques described herein, provide high concentration efficiency without the high cost associated with constructing a parabolic or other complicated shaped reflector is avoided. Hemisphere shaped reflectors can be relatively easily manufactured without specialized tools or production facilities (e.g. using inflatable spherical molds or templates). In some cases the reflectors may be produced at or near the site where the collector is to be deployed, thereby avoiding the need for extensive transport or shipping.

One embodiment of the invention relates to a light concentrator apparatus including a reflector with an open substantially hemispherical reflecting surface characterized by a radius R, and an aperture for admitting light onto the hemispherical reflecting surface. The light concentrator apparatus further includes a movable elongated light collector having a first end located proximal to the reflecting surface; and extending along a longitudinal axis in a direction substantially normal to the reflecting surface to a second end. The light concentrator further includes a tracker configured to move the first end of the collector to points proximal to the reflecting surface.

Another embodiment relates to a method including obtaining a light concentrator apparatus including a reflector, receiving light from a source with the concentrator; and concentrating light from the source onto the collector. The reflector includes an open substantially hemispherical reflecting surface characterized by a radius R, and an aperture for admitting light onto the hemispherical reflecting surface. The reflector further includes a movable elongated light collector having a first end located proximal to the reflecting surface; and extending along a longitudinal axis in a direction substantially normal to the reflecting surface to a second end. The reflector further includes a tracker configured to move the first end of the collector to points proximal to the reflecting surface.

Still another embodiment relates to a method of making a light concentrator including obtaining a reflector comprising an open substantially hemispherical reflecting surface characterized by a radius R, and an aperture for admitting light onto the hemispherical reflecting surface. The method further includes obtaining a movable elongated light collector having a first end located proximal to the reflecting surface and extending along a longitudinal axis in a direction substantially normal to the reflecting surface to a second end; and obtaining a tracker configured to move the first end of the collector to points proximal to the reflecting surface.

In one aspect, a light concentrator apparatus is disclosed including: a reflector including: an open substantially hemispherical reflecting surface characterized by a radius R; and an aperture for admitting light onto the hemispherical reflecting surface; a movable elongated light collector having a first end located proximal to the reflecting surface, the collector extending from the first end along a longitudinal axis in a direction substantially normal to the reflecting surface to a second end; and a tracker configured to move the first end of the collector to points proximal to the reflecting surface.

In some embodiments, the reflector concentrates onto the collector substantially all light is incident on the aperture at angles to the longitudinal axis of the collector less than or equal to an acceptance angle of θ radians.

In some embodiments, the movable light collector includes a cylinder extending along the longitudinal axis.

In some embodiments, the cylinder has a length L equal to or greater than about 0.5 R.

In some embodiments, the cylinder has a radius equal to or greater than about R multiplied by θ, where θ is in units of radians.

In some embodiments, the aperture is a substantially circular aperture defined by equator of the open hemispherical reflecting surface.

In some embodiments, the light concentrated onto the collector has an intensity distribution which varies by about 200% or less over a length extending 0.4 R from the first end.

In some embodiments, the light collector includes an absorber which converts incident light into another form of energy.

In some embodiments, the absorber includes a photovoltaic material.

In some embodiments, the absorber includes a thermoelectric material.

In some embodiments, the absorber includes a thermal absorber.

In some embodiments, the thermal absorber includes a selective surface located in an evacuated enclosure.

In some embodiments, the thermal absorber transfers heat to a fluid.

In some embodiments, the substantially hemispherical reflecting surface is a metallized surface.

In some embodiments, the tracker is configured to substantially align the longitudinal axis with a direction of incident radiation from a source.

In some embodiments, the source is the sun.

In some embodiments, the tracker includes an elongated member extending from the second end of the collector along a direction substantially normal to the reflecting surface to a pivot located near the aperture.

In some embodiments, the tracker includes an actuator configured to pivot the elongated member.

Some embodiments include a controller in communication with the tracker to maintain the collector at a desired position to substantially align the longitudinal axis with a direction of incident radiation from the source.

In some embodiments, the controller determines the desired position based on a time or date.

In some embodiments, the source is the sun, and where the controller stores information indicative of the position of the sun in the sky at a plurality of times.

Some embodiments include at least one sensor which produces a signal indicative of the amount of light concentrated onto the collector, and where the controller determines the desired position based on the signal.

Some embodiments include a closed loop servo configured to adjust the position of the collector to maintain the alignment of the longitudinal axis with a direction of incident radiation from the source in response to changes in the position of the source.

In some embodiments, acceptance angle θ is equal to about 0.5 degrees or more

In some embodiments, the acceptance angle θ is equal to about 1 degrees or more.

In some embodiments, the acceptance angle θ is equal to about 2 degrees or more.

In some embodiments, the acceptance angle θ is equal to about 5 degrees or more.

In some embodiments, where the apparatus is mounted on a surface and the reflector is fixed relative to the surface.

In some embodiments, the surface is the surface of the earth.

In some embodiments, the admitted light is solar light.

In another aspect, a method including: obtaining a light concentrator apparatus including a reflector including: an open substantially hemispherical reflecting surface characterized by a radius R; and an aperture for admitting light onto the hemispherical reflecting surface; a movable elongated light collector having a first end located proximal to the reflecting surface, the collector extending from the first end along a longitudinal axis in a direction substantially normal to the reflecting surface to a second end; and a tracker configured to move the first end of the collector to points proximal to the reflecting surface; receiving light from a source with the concentrator; and concentrating light from the source onto the collector.

In some embodiments, concentrating light from the source onto the collector includes concentrating onto the collector substantially all light that is incident on the aperture at angles to the longitudinal axis of the collector less than or equal to an acceptance angle θ.

In some embodiments, the movable light collector includes a cylinder extending along the longitudinal axis.

In some embodiments, the cylinder has a length L equal to or greater than about 0.5 R.

In some embodiments, the cylinder has a radius equal to or greater than about R multiplied by θ, where θ is in units of radians.

In some embodiments, the aperture is a substantially circular aperture defined by the equator of the open hemispherical reflecting surface.

In some embodiments, the light concentrated onto the collector has an intensity distribution which varies by about 200% or less over a length extending 0.4 R from the first end

In some embodiments, the light collector includes an absorber, and further including converting light incident on the collector into another form of energy.

In some embodiments, the absorber includes a photovoltaic material.

In some embodiments, the absorber includes a thermoelectric material.

In some embodiments, the absorber includes a thermal absorber.

In some embodiments, the thermal absorber includes a selective surface located in an evacuated enclosure.

Some embodiments include using the thermal absorber to transfer heat to a fluid.

In some embodiments, the substantially hemispherical reflecting surface is a metalized surface.

Some embodiments include using the tracker to align the longitudinal axis with a direction of incident radiation from a source.

In some embodiments, the source is the sun.

In some embodiments, the tracker includes an elongated member extending from the second end of the collector along a direction substantially normal to the reflecting surface to a pivot located near the aperture.

In some embodiments, the tracker includes an actuator configured to pivot the elongated member.

Some embodiments include using the tracker to maintain the collector at a desired position to substantially align the longitudinal axis with a direction of incident radiation from the source.

Some embodiments include determining the desired position based on a time or date.

In some embodiments, the source is the sun, and the method includes determining the desired position based on a time or date and on stored information indicative of the position of the sun in the sky at a plurality of times.

Some embodiments include using at least one sensor to generate a signal indicative of the amount of light concentrated onto the collector; and determining the desired position based on the signal.

Some embodiments include using a closed loop servo to adjust the position of the collector to maintain the alignment of the longitudinal axis with a direction of incident radiation from the source in response to changes in the position of the source.

In some embodiments, the acceptance angle θ is equal to about 0.5 degrees or more

In some embodiments, the acceptance angle θ is equal to about 1 degrees or more.

In some embodiments, the acceptance angle θ is equal to about 2 degrees or more.

In some embodiments, the acceptance angle θ is equal to about 5 degrees or more.

Some embodiments include mounting the collector on a surface where the reflector is fixed relative to the surface.

In some embodiments, the surface is the surface of the earth.

In some embodiments, the admitted light is solar light.

In another aspect, a method of making a light concentrator is disclosed including:

obtaining a reflector including: an open substantially hemispherical reflecting surface characterized by a radius R; and an aperture for admitting light onto the hemispherical reflecting surface; obtaining a movable elongated light collector having a first end located proximal to the reflecting surface; the collector extending from the first end to a second end along a longitudinal axis in a direction substantially normal to the reflecting surface; and obtaining a tracker configured to move the first end of the collector to points proximal to the reflecting surface.

Some embodiments include: shipping the collector and tracker unassembled to a desired location for the light concentrator; providing an inflatable balloon at the desired location; inflating the balloon to form an at least partially spherical surface; using the partially spherical surface to form the reflector at the desired location; and assembling the reflector, tracker, and collector to form the light concentrator at the desired location.

In some embodiments, the balloon is made of a substantially inelastic material having a predetermined shape when fully inflated.

In some embodiments, the balloon is made of Mylar.

Various embodiments may feature any of the above described elements, either alone or in any suitable combination.

It is to be understood that both the foregoing general description and the following detailed description are exemplary and explanatory only, and are not restrictive of the invention as claimed.

### BRIEF DESCRIPTION OF THE DRAWINGS

These and other features, aspects, and advantages of the present invention will become apparent from the following description, appended claims, and the accompanying exemplary embodiments shown in the drawings, which are briefly described below.

FIG. 1 is a schematic diagram of an energy conversion system according to an exemplary embodiment.

FIG. 2 is a cross section of an energy transducer for the energy conversion system of FIG. 1 according to an exemplary embodiment.

FIG. 3 is a schematic cross section of a portion of the energy conversion system of FIG. 1 according to an exemplary embodiment showing the collection of incident light rays that are normal to the orientation of the concentrator.

FIG. 4 is a schematic cross section of a portion of the energy conversion system of FIG. 1 according to an exemplary embodiment showing the collection of incident light rays that are angled relative to the orientation of the concentrator.

FIG. 5 is a schematic side view of an energy conversion system showing skewed incident rays according to an exemplary embodiment.

FIG. 6 is a schematic top view of an energy conversion system showing skewed incident rays according to an exemplary embodiment.

FIG. 7 is a schematic isometric view of an energy conversion system showing skewed incident rays according to an exemplary embodiment.

FIG. 8 is a graph showing the irradiance distribution on the transducer along the length of the transducer according to an exemplary embodiment.

### DETAILED DESCRIPTION

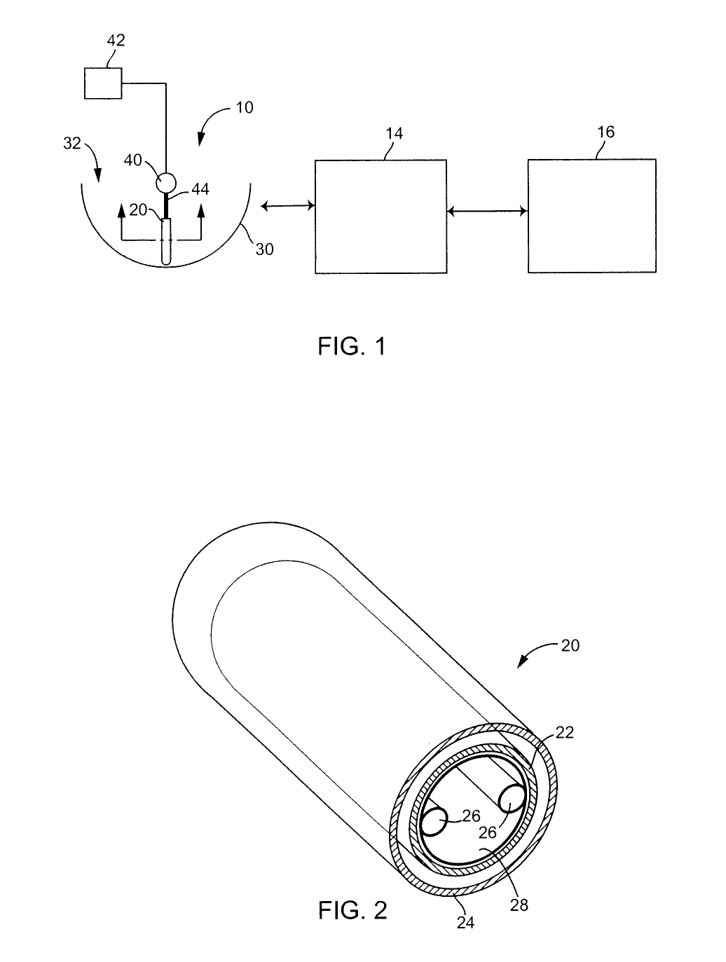

Referring to FIG. 1, a solar energy collector apparatus 10 (e.g., solar energy conversion system, solar energy conversion apparatus, etc.) is shown according to an exemplary embodiment. The solar energy concentrator 10 collects solar energy and converts it to another form of energy that is useful to do work using an energy collector 20 (e.g., receiver, collector, etc.). According to an exemplary embodiment, the energy collector 20 is a thermal vacuum tube that is configured to convert the solar energy to heat in a working fluid (e.g., water, oil, glycol, a molten salt, etc) or a mixture of working fluids. The working fluid is then circulated (e.g., with natural convection, with a pump, etc.) through a fluid system 14 to a device 16. In the device 16, the working fluid may do work or may exchange heat with another fluid to provide heated air or water (e.g., for residential use).

As shown best in FIG. 2, the collector 20 (e.g., energy transducer, energy absorber, light absorber, etc.) comprises an inner tube 22 and an outer tube 24 with an inner diameter larger than the outer diameter of the inner tube 22. According to an exemplary embodiment, the inner tube 22 and the outer tube 24 is formed from a transparent material such as glass. The inner tube 22 and the outer tube 24 are closed at one end to form a hemisphere and are fused together at the other end. The annular space between the inner tube 22 and the outer tube 24 is evacuated and sealed to form a partial vacuum. According to other exemplary embodiments, the collector may comprise a single transparent tube and lack an intermediate space with a partial vacuum.

The inner tube 22 houses one or more pipes 26 through which a working fluid is circulated. The pipes 26 are formed from a material with a relatively high thermal conductivity to facilitate the transfer of heat between the air inside the inner tube 22 and the working fluid. The pipes may be formed, for example, from a metal such as aluminum, copper, brass, etc. According to an exemplary embodiment, the collector 20 includes a U-shape pipe that is connected to a manifold. The working fluid flows into the collector 20 along one arm and out of the collector 20 through the other arm. The pipes 26 may connect directly to a manifold by means of elongated piercings in a manifold wall through which the pipes 26 are inserted and bonded to the manifold wall by bracing, welding, etc.

According to an exemplary embodiment, an absorber fin 28 is mounted between the inner tube 22 and the pipes 26 to further facilitate the heat transfer to the heat-transfer fluid flowing in the pipes 26. The absorber fin 28 may be ultrasound-welded or otherwise coupled to the pipes 26 at discrete locations within an external surface of the pipes 26. The pipes 26 may be coated with a coating that promotes absorption of solar radiation incident on the solar energy concentrator 10.

The solar energy absorbed by the collector 20 passes through the outer tube 24 and the inner tube 22 to heat the absorber fin 28 and pipes 26 and the working fluid inside the pipes 26 with a radiation heat transfer. The partial vacuum between the inner tube 22 and the outer tube 24 reduces the energy lost to the outside environment from the pipes 26 due to conduction or convection.

Other types of pipes or tubes may be used without limitation. For example, the collector 20 may house a counter-flow pipe design which utilizes a coaxial pipe in which the heat-transfer fluid flows through an internal pipe and returns through an external side that is attached to the absorber fin 28. The collector 20 further may comprise a Dewar collector in which the heat-transfer fluid flows into the collector 20 through a metal pipe that is open at the end. The heat-transfer fluid flow returns along the internal surface of inner tube 22.

While the collector 20 is described above as a thermal absorber, the collector 20 may be any other suitable energy transducer. For example, according to another embodiment, the apparatus 10 may comprise a collector that includes a photovoltaic material. Such a collector may convert photons from incident solar energy to an electrical voltage. According to another exemplary embodiment, the apparatus 10 may comprise a collector that includes a thermoelectric material. The thermoelectric material is heated by the solar radiation and converts the heat directly to a voltage.

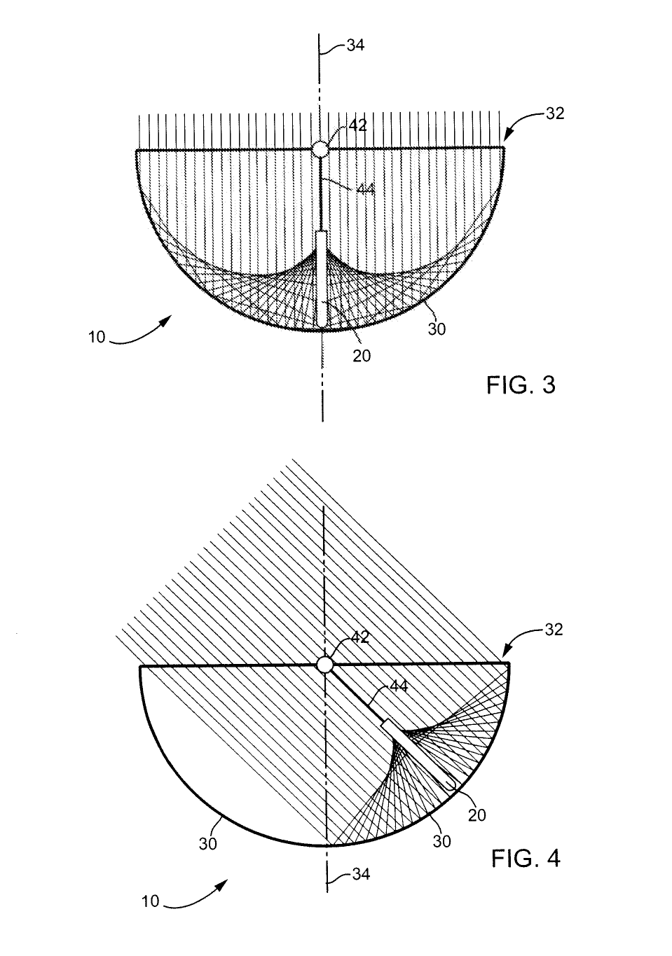

As shown in more detail in FIGS. 3 and 4, a reflector 30 is provided to increase the amount of light that is directed towards the energy collector 20, thereby increasing the amount of solar energy that may be converted by the energy collector 20. The reflector 30 collects solar energy over a relatively large area (e.g., larger than the area of the area of the energy collector 20) and directs it through an output toward the energy collector 20. The reflector 30 is a curved reflector with an open end or aperture 32 that receives light. The inner surface of the reflector reflects incident light such as sunlight onto the energy collector 20.

According to an exemplary embodiment, the reflector 30 is a hemispherical body. Incident light rays (e.g., solar rays, etc) are directed towards the collector 20 by the reflecting surface of the reflector 30. Because the reflector 30 is a hemispherical body, parallel solar rays are focused on a line rather than on a point due to spherical aberration. While a parabolic reflector can focus incoming parallel rays to a single point, such reflectors are difficult and costly to manufacture. A hemispherical reflector, by contrast, can be made relatively easily and inexpensively compared to a parabolic reflector.

The reflector 30 may be formed, for instance, with the use of an inflated, balloon-like structure. According to one exemplary embodiment, the reflector 30 may be formed using a balloon or other inflatable body. Such an inflatable body can be easily shipped and inflated on-site. The inflated balloon or other similarly shaped structure can then be used as a mold to create the hemispherical reflector 30. for example, in some embodiments, a material such as fiberglass-reinforced resin or another suitable material is applied to the inflated balloon or other structure. Once dried, the material is removed from the mold and at least a portion of the interior surface of the reflector 30 is metalized or otherwise treated to become reflective.

In some embodiments, the inflatable body may be made of a relatively inelastic material having a predetermined shape (e.g. a sphere of a given radius). such as biaxially-oriented polyethylene terephthalate, which is marketed under a variety of trade names such as Mylar, Melinex and Hostaphan. As will be understood by those skilled in the art, any other suitable technique for producing a hemispherical reflector may be used.

The collector 20 is suspended in the space defined by the hemispherical reflector 30 and oriented radially relative to the reflecting surface of the reflector 30 such that it is normal to the reflecting surface of the reflector 30. By orienting the collector 20 along the radius of the reflector 30, the rays are directed at the collector 20 despite spherical aberration. In a first position, shown in FIG. 3, the collector 20 is aligned with the central axis 34 of the reflector 30. In this position, incoming rays that are parallel to the central axis 34 (e.g., and have an angle of incidence of 0) are reflected onto the central axis 34. The minimum length of the collector 20 can be described with the equation

$$L = \frac{R}{2} ,$$

where L is the minimum length of the collector 20 and R is the radius of curvature of the reflector 30. At such a length, substantially all of the parallel light rays striking any reflective portion of the reflector 30 can be collected by the collector 20.

As shown in FIG. 8, the light concentrated onto the collector 20 has a intensity distribution which varies by about 200% or less over a length extending 0.4 R from the first end. The intensity of the light absorbed is generally greatest at the end of the collector 20 remote from the reflective surface of the reflector 30 and decreases towards the end of the collector proximal to the reflective surface of the reflector 30. The intensity at the very tip of the second end of the collector 20 rises sharply and is less predictable and regular due to the geometry of the glass tubes 22 and 24 and the inner pipes 26.

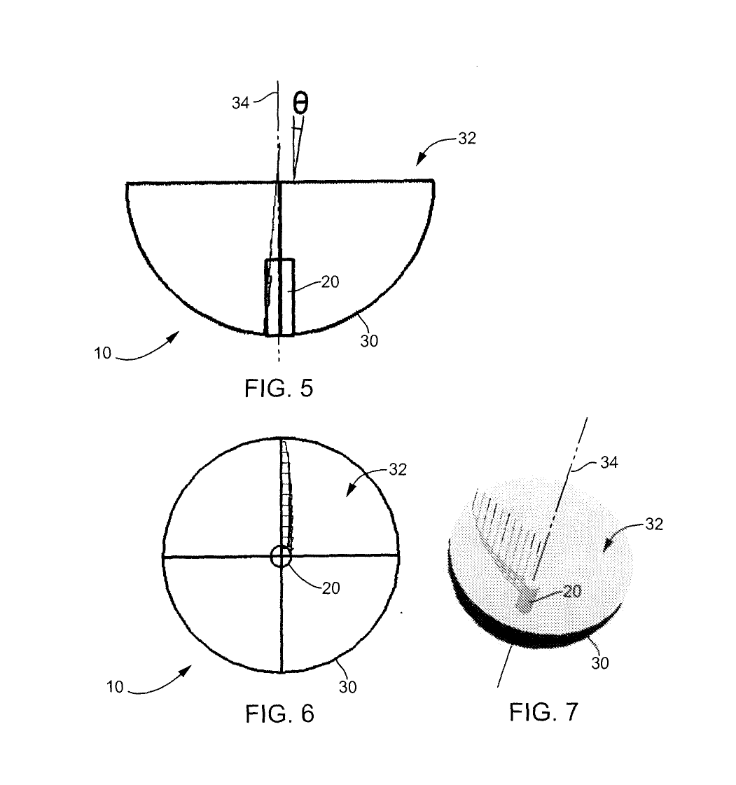

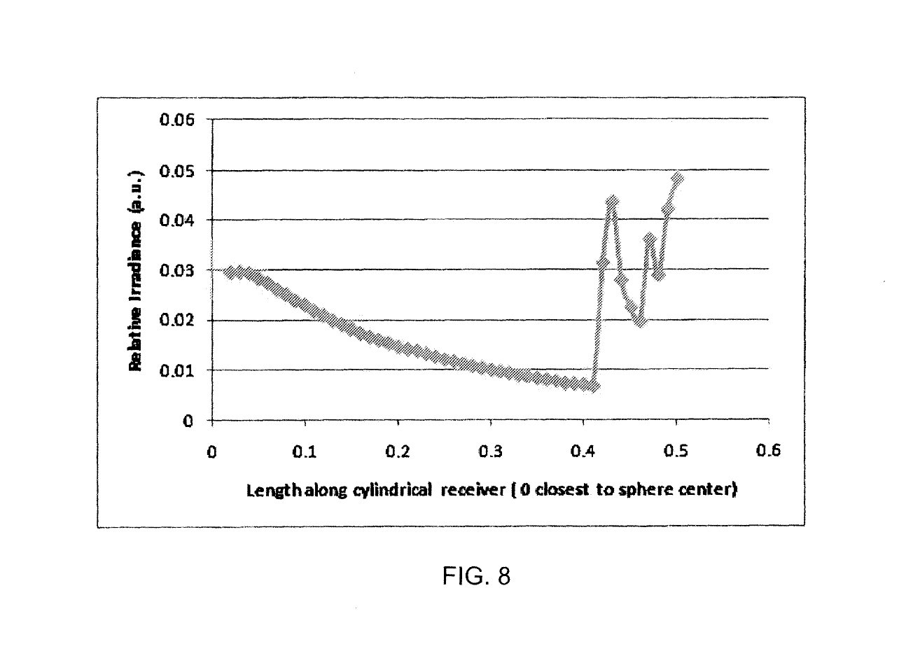

Not all incident light rays are parallel and may be, instead, skewed. Such skew rays may still be captured by the collector 20 if the collector 20 has a sufficient diameter, as shown in FIGS. 5-7. According to an exemplary embodiment, the minimum radius of the collector 20 can be determined with the equation r=Rθ, where r is the radius of the collector 20, R is the radius of the reflector 30, and θ is the angle of incidence of the skew ray measured in radians. By increasing the radius of the collector 20, rays skewed at a greater angle can still be captured by the collector 20, increasing the amount of energy captured by the apparatus 10. According to an exemplary embodiment, the collector 20 has a radius that allows it to collect rays skewed at an angle equal to about 0.5 degrees or more. In a preferred embodiment, the collector 20 has a radius that allows it to collect rays skewed at an angle equal to about 1 degree or more. In a more preferred embodiment, the collector 20 has a radius that allows it to collect rays skewed at an angle equal to about 2 degrees or more. In a particularly preferred embodiment, the collector 20 has a radius that allows it to collect rays skewed at an angle equal to about 5 degrees or more

The concentration of light absorbed by the collector 20 is determined by dividing the input area of the reflector 30 (e.g., the surface area of the open end 32) by the surface area of the collector 20 (e.g., the area of the cylindrical side wall of the outer tube 24). The concentration can be described by the equation

$$C = \frac{π {R}^{2}}{2 π r \frac{R}{2}} ,$$

where r is the radius of the transducer, R is the radius of the reflector 30, and can be simplified to

$$C = \frac{1}{θ} .$$

The overall concentration factor of the apparatus 10 may be adjusted by controlling the radius of the collector 20 selected.

As the position of the sun in the sky changes over the course of the day and over the course of the year, the angle at which the solar rays hit the concentrator also change. As the angle of incidence varies from 0 (as shown in FIG. 3) to another angle (as shown in FIG. 4), the radial line onto which the rays are reflected also varies.

The collector 20 is mounted such that it pivots about the center of curvature of the reflector 30. Rather than move the reflector 30 so that the central axis 34 is aligned with the incoming light rays, the collector 20 can be moved by a tracker 40 so that it is parallel with the incoming light rays and aligned with the radial line upon which the rays are reflected by the reflector 30. The reflector 30, by contrast, is not moved and stays stationary to a generally static mounting surface such as the surface of the Earth.

Because it only has to move the collector 20, the tracker 40 can be a smaller, less expensive mechanism than one configured to move the entire reflector 30. The tracker 40 is a two axis tracker that is able to move the collector 20, pivoting at the center of curvature of the reflector 30. The transducer is moved in the space defined by the hemispherical reflector 30. According to one exemplary embodiment, the tracker 40 is a servo motor that is in communication with a controller 42 and is coupled to the collector 20 with an arm 44. The arm 44 is coincident with the longitudinal axis of the elongated collector 20 and is normal to the surface of the reflector 30.

The controller 42 maintains the collector 20 at a desired position to substantially align the longitudinal axis of the collector 20 with a direction of incident radiation from the source. According to an exemplary embodiment, the source of the incident radiation is the sun and the controller 42 stores information indicative of the position of the sun in the sky at a plurality of times. Such information may be stored, for example, as a look-up table or as an approximating equation. The controller 42 determines the desired position based on a time or date and sends a control signal to the tracker 40 to move the collector 20 to the desired position.

According to another embodiment, the apparatus 10 may further include one or more sensors which produces a signal indicative of the amount of light concentrated onto the collector 20. The controller 42 receives signal data from the sensors and determines the desired position of the collector 20 based on the signal from the sensors. The controller 42 communicates with a tracker 40 (e.g., a closed loop servo) to adjust the position of the collector 20 to maintain the alignment of the longitudinal axis of the collector 20 with a direction of incident radiation from the source in response to changes in the position of the source.

According to another exemplary embodiment, the controller 42 may use both stored data and sensor data to determine the optimal positioning of the collector 20. For instance, the controller 42 may move the tracker 40 with stored data and use sensor data as a diagnostic tool to slightly adjust the position of the collector 20. Such sensor data may be useful if, for example, the base upon which the apparatus 10 shifts or moves over time.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above.

All publications, patent applications, issued patents, and other documents referred to in this specification are herein incorporated by reference as if each individual publication, patent application, issued patent, or other document were specifically and individually indicated to be incorporated by reference in its entirety. Definitions that are contained in text incorporated by reference are excluded to the extent that they contradict definitions in this disclosure.

For the purposes of this disclosure and unless otherwise specified, “a” or “an” means “one or more.”

As used herein, the term “comprising” is intended to mean that the compositions and methods include the recited elements, but not excluding others. “Consisting essentially of” when used to define compositions and methods, shall mean excluding other elements of any essential significance to the combination for that intended purpose. “Consisting of” shall mean excluding more than trace elements of other ingredients and substantial method steps for making or using the concentrators or articles of this invention.

The construction and arrangements of the solar energy concentrator, as shown in the various exemplary embodiments, are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Some elements shown as integrally formed may be constructed of multiple parts or elements, the position of elements may be reversed or otherwise varied, and the nature or number of discrete elements or positions may be altered or varied. The order or sequence of any process, logical algorithm, or method steps may be varied or re-sequenced according to alternative embodiments. Other substitutions, modifications, changes and omissions may also be made in the design, operating conditions and arrangement of the various exemplary embodiments without departing from the scope of the present disclosure.

1. A light concentrator apparatus comprising:
a reflector comprising:
an open substantially hemispherical reflecting surface characterized by a radius R; and
an aperture for admitting light onto the hemispherical reflecting surface;
a movable elongated light collector having a first end located proximal to the reflecting surface, the collector extending from the first end along a longitudinal axis in a direction substantially normal to the reflecting surface to a second end; and
a tracker configured to move the first end of the collector to points proximal to the reflecting surface.

2. The apparatus of claim 1, wherein the reflector concentrates onto the collector substantially all light is incident on the aperture at angles to the longitudinal axis of the collector less than or equal to an acceptance angle of θ radians.

3. The apparatus of claim 1, wherein the movable light collector comprises a cylinder extending along the longitudinal axis.

4. The apparatus of claim 3, where the cylinder has a length L equal to or greater than about 0.5 R.

5. The apparatus of claim 4, wherein the cylinder has a radius equal to or greater than about R multiplied by θ, where θ is in units of radians.

6. The apparatus of claim 5, wherein the aperture is a substantially circular aperture defined by equator of the open hemispherical reflecting surface.

7. The apparatus of claim 4, wherein the light concentrated onto the collector has an intensity distribution which varies by about 200% or less over a length extending 0.4 R from the first end.

8. The apparatus of claim 2, wherein the light collector comprises an absorber which converts incident light into another form of energy.

9. The apparatus of claim 8, wherein the absorber comprises a photovoltaic material.

10. The apparatus of claim 8, wherein the absorber comprises a thermoelectric material.

11. The apparatus of claim 8, wherein the absorber comprises a thermal absorber.

12. The apparatus of claim 11, wherein the thermal absorber comprises a selective surface located in an evacuated enclosure.

13. The apparatus of claim 11, wherein the thermal absorber transfers heat to a fluid.

14. The apparatus of claim 1, wherein the substantially hemispherical reflecting surface is a metallized surface.

15. The apparatus of claim 2, wherein the tracker is configured to substantially align the longitudinal axis with a direction of incident radiation from a source.

16. The apparatus of claim 15, wherein the source is the sun.

17. The apparatus of claim 15, wherein the tracker comprises an elongated member extending from the second end of the collector along a direction substantially normal to the reflecting surface to a pivot located near the aperture.

18. The apparatus of claim 17, wherein the tracker comprises an actuator configured to pivot the elongated member.

19. The apparatus of claim 15, further comprising a controller in communication with the tracker to maintain the collector at a desired position to substantially align the longitudinal axis with a direction of incident radiation from the source.

20. The apparatus of claim 19, wherein the controller determines the desired position based on a time or date.

21. The apparatus of claim 20, wherein the source is the sun, and wherein the controller stores information indicative of the position of the sun in the sky at a plurality of times.

22. The apparatus of claim 19, further comprising at least one sensor which produces a signal indicative of the amount of light concentrated onto the collector, and wherein the controller determines the desired position based on the signal.

23. The apparatus of claim 22, comprising a closed loop servo configured to adjust the position of the collector to maintain the alignment of the longitudinal axis with a direction of incident radiation from the source in response to changes in the position of the source.

24. The apparatus of claim 2, wherein the acceptance angle θ is equal to about 0.5 degrees or more.

25. The apparatus of claim 2, wherein the acceptance angle θ is equal to about 1 degrees or more.

26. The apparatus of claim 2, wherein the acceptance angle θ is equal to about 2 degrees or more.

27. The apparatus of claim 2, wherein the acceptance angle θ is equal to about 5 degrees or more.

28. The apparatus of claim 1, wherein the apparatus is mounted on a surface and the reflector is fixed relative to the surface.

29. The apparatus of claim 28, wherein the surface is the surface of the earth.

30. The apparatus of claim 1, wherein the admitted light is solar light.

31. A method comprising:
obtaining a light concentrator apparatus comprising:
a reflector comprising:
an open substantially hemispherical reflecting surface characterized by a radius R; and
an aperture for admitting light onto the hemispherical reflecting surface;
a movable elongated light collector having a first end located proximal to the reflecting surface, the collector extending from the first end along a longitudinal axis in a direction substantially normal to the reflecting surface to a second end; and
a tracker configured to move the first end of the collector to points proximal to the reflecting surface;
receiving light from a source with the concentrator; and
concentrating light from the source onto the collector.

32. The method of claim 31, wherein concentrating light from the source onto the collector comprises concentrating onto the collector substantially all light that is incident on the aperture at angles to the longitudinal axis of the collector less than or equal to an acceptance angle θ.

33. The method of claim 32, wherein the movable light collector comprises a cylinder extending along the longitudinal axis.

34. The method of claim 33, where the cylinder has a length L equal to or greater than about 0.5 R.

35. The method of claim 34, wherein the cylinder has a radius equal to or greater than about R multiplied by θ, where θ is in units of radians.

36. The method of claim 35, wherein the aperture is a substantially circular aperture defined by the equator of the open hemispherical reflecting surface.

37. The method of claim 34, wherein the light concentrated onto the collector has an intensity distribution which varies by about 200% or less over a length extending 0.4 R from the first end.

38. The method of claim 32, wherein the light collector comprises an absorber, and further comprising converting light incident on the collector into another form of energy.

39. The method of claim 38, wherein the absorber comprises a photovoltaic material.

40. The method of claim 38, wherein the absorber comprises a thermoelectric material.

41. The method of claim 38, wherein the absorber comprises a thermal absorber.

42. The method of claim 38 wherein the thermal absorber comprises a selective surface located in an evacuated enclosure.

43. The method of claim 41, comprising using the thermal absorber to transfer heat to a fluid.

44. The method of claim 31, wherein the substantially hemispherical reflecting surface is a metallized surface.

45. The method of claim 32, comprising using the tracker to align the longitudinal axis with a direction of incident radiation from a source.

46. The method of claim 45, wherein the source is the sun.

47. The method of claim 45, wherein the tracker comprises an elongated member extending from the second end of the collector along a direction substantially normal to the reflecting surface to a pivot located near the aperture.

48. The method of claim 47, wherein the tracker comprises an actuator configured to pivot the elongated member.

49. The method of claim 45, further using the tracker to maintain the collector at a desired position to substantially align the longitudinal axis with a direction of incident radiation from the source.

50. The method of claim 49, comprising determining the desired position based on a time or date.

51. The method of claim 50, wherein the source is the sun, and comprising determining the desired position based on a time or date and on stored information indicative of the position of the sun in the sky at a plurality of times.

52. The method of claim 49, further comprising using at least one sensor to generate a signal indicative of the amount of light concentrated onto the collector; and determining the desired position based on the signal.

53. The method of claim 52, comprising using a closed loop servo to adjust the position of the collector to maintain the alignment of the longitudinal axis with a direction of incident radiation from the source in response to changes in the position of the source.

54. The method of claim 32, wherein the acceptance angle θ is equal to about 0.5 degrees or more.

55. The method of claim 32, wherein the acceptance angle θ is equal to about 1 degrees or more.

56. The method of claim 32, wherein the acceptance angle θ is equal to about 2 degrees or more.

57. The method of claim 32, wherein the acceptance angle θ is equal to about 5 degrees or more.

58. The method of claim 31, comprising mounting the collector on a surface wherein the reflector is fixed relative to the surface.

59. The method of claim 58, wherein the surface is the surface of the earth.

60. The method of claim 31, wherein the admitted light is solar light.

61. A method of making a light concentrator comprising
obtaining a reflector comprising:
an open substantially hemispherical reflecting surface characterized by a radius R; and
an aperture for admitting light onto the hemispherical reflecting surface;
obtaining a movable elongated light collector having a first end located proximal to the reflecting surface; the collector extending from the first end to a second end along a longitudinal axis in a direction substantially normal to the reflecting surface; and
obtaining a tracker configured to move the first end of the collector to points proximal to the reflecting surface.

62. The method of claim 61, comprising:
shipping the collector and tracker unassembled to a desired location for the light concentrator; providing an inflatable balloon at the desired location;
inflating the balloon to form an at least partially spherical surface;
using the partially spherical surface to form the reflector at the desired location; and
assembling the reflector, tracker, and collector to form the light concentrator at the desired location.

63. The method of claim 62, wherein the balloon is made of a substantially inelastic material having a predetermined shape when fully inflated.

64. The method of claim 63, wherein the balloon is made of Mylar.
